(19) United States
(12) Patent Application Publication
(10) Pub. No.: US 2025/0359367 A1
(43) Pub. Date: Nov. 20, 2025

(54) IMAGE SENSOR

(71) Applicant: Samsung Electronics Co., Ltd., Suwon-si (KR)

(72) Inventors: Youna LEE, Suwon-si (KR); Dongmo IM, Suwon-si (KR)

(73) Assignee: Samsung Electronics Co., Ltd., Suwon-si (KR)

(21) Appl. No.: 19/010,538

(22) Filed: Jan. 6, 2025

(30) Foreign Application Priority Data
May 14, 2024 (KR) 10-2024-0063120
Jun. 10, 2024 (KR) 10-2024-0074820

(51) Int. Cl. H10F 39/00; H10F 39/18

(52) U.S. Cl. CPC H10F 39/80373; H10F 39/182; H10F 39/8053; H10F 39/8063; H10F 39/807

(57) ABSTRACT

Provided is an image sensor. The image sensor includes a substrate including a first face and a second face opposite to each other, a deep separation part in the substrate and defining a first light-receiving region, the first light-receiving region including first to fourth side surfaces arranged clockwise in a plan view, a shallow separation part in the substrate and adjacent to the first face, the shallow separation part defining a first active part in the first light-receiving region, and the first active part having a first active region adjacent to the first side surface and a second active region adjacent to the second side surface in a plan view, and a reset gate electrode on the first active part.

### CROSS-REFERENCE TO RELATED APPLICATIONS

This U.S. non-provisional patent application claims priority under 35 U.S.C. § 119 of Korean Patent Application Nos. 10-2024-0063120, filed on May 14, 2024, and 10-2024-0074820, filed on Jun. 10, 2024, the entire contents of which are hereby incorporated by reference.

### BACKGROUND

Various example embodiments herein relate to an image sensor.

Image sensors are semiconductor devices that convert an optical image into an electric signal. The image sensors may be classified into a charge coupled device (CCD)-type image sensor and a complementary metal oxide semiconductor (CMOS)-type image sensor. The CMOS-type image sensor is abbreviated to a CIS. The CIS includes a plurality of two-dimensionally arranged pixels. Each of the pixels includes a photodiode (PD). The photodiode serves to convert incident light into an electric signal.

### SUMMARY

Various example embodiments provide an image sensor capable of providing clear image quality.

Various example embodiments of the inventive concepts provide an image sensor including a substrate including a first face and a second face opposite to each other, a deep separation part in the substrate and defining a first light-receiving region, the first light-receiving region including first to fourth side surfaces arranged clockwise in a plan view, a shallow separation part in the substrate and adjacent to the first face, the shallow separation part defining a first active part in the first light-receiving region, and the first active part having a first active region adjacent to the first side surface and a second active region adjacent to the second side surface in a plan view, and a reset gate electrode on the first active part. The reset gate electrode includes a first gate portion on the first active region and a second gate portion on the second active region, and the first gate portion and the second gate portion are connected to each other.

In various example embodiments of the inventive concepts, an image sensor includes a substrate including a first face and a second face opposite to each other, a deep separation part in the substrate and defining a first light-receiving region, a shallow separation part in the substrate and adjacent to the first face, the shallow separation part defining a first active part and a second active part in the first light-receiving region, and the first active part having an “L” shape in a plan view, a reset gate electrode on the first active part, a transfer gate electrode on the second active part, and a floating diffusion region in the second active part adjacent to the transfer gate electrode. The first active part includes a channel region overlapping the reset gate electrode and a first impurity region not overlapping the reset gate electrode, and a first distance between the second active part and the first impurity region is larger than a second distance between the second active part and the channel region.

In various example embodiments of the inventive concepts, an image sensor includes a substrate including a first face and a second face opposite to each other, a deep separation part in the substrate and separating first and second group regions arranged side by side in a first direction such that the deep separation part is in the first and second group regions and separates first to eighth light-receiving regions, the first to fourth light-receiving regions are arranged clockwise and constitute the first group region, and the fifth to eighth light-receiving regions are arranged clockwise and constitute the second group region, a shallow separation part in the substrate and adjacent to the first face in the first to eighth light-receiving regions, the shallow separation part defining a first active part and a second active part in each of the first to eighth light-receiving regions, a reset gate electrode on the first active part in any one of the first to fourth light-receiving regions and having an “L” shape in a plan view, transfer gate electrodes respectively arranged on the second active parts of the first to eighth light-receiving regions, a first floating diffusion region at a center of the first group region, a second floating diffusion region at a center of the second group region, a first line connecting the first floating diffusion region to the second floating diffusion region, an interlayer insulating layer covering the first face, the reset gate electrode, the transfer gate electrodes, and the first line, a first color filter on the second face and covering the first group region, a second color filter on the second face and covering the second group region, and microlenses arranged on the first and second color filters and respectively overlapping the first to eighth light-receiving regions.

### BRIEF DESCRIPTION OF THE FIGURES

The accompanying drawings are included to provide a further understanding of the inventive concepts, and are incorporated in and constitute a part of this specification. The drawings illustrate various example embodiments of the inventive concepts and, together with the description, serve to explain principles of the inventive concepts. In the drawings:

FIG. 1 is a schematic layout of an image sensor according to various example embodiments of the inventive concepts;

FIG. 2 is a cross-sectional view taken along line A-A′ of FIG. 1;

FIG. 3 is a cross-sectional view taken along line B-B′ of FIG. 1;

FIG. 4 is a perspective view of the transfer gate electrode of FIGS. 1 and 3;

FIG. 5 is a layout of an image sensor according to various example embodiments of the inventive concepts;

FIG. 6 is a cross-sectional view taken along line B-B′ of FIG. 5;

FIG. 7 is a layout of an image sensor according to various example embodiments of the inventive concepts;

FIG. 8 is a plan view of an image sensor according to various example embodiments of the inventive concepts;

FIG. 9 is a layout of an image sensor according to various example embodiments of the inventive concepts;

FIG. 10 is a cross-sectional view taken along line C-C′ of FIG. 9 according to various example embodiments of the inventive concepts;

FIG. 11 is a circuit diagram of the image sensor of FIGS. 9 and 10;

FIG. 12 is a layout of an image sensor according to various example embodiments of the inventive concepts;

FIG. 13 is a cross-sectional view of an image sensor according to various example embodiments of the inventive concepts;

FIG. 14 is a cross-sectional view of an image sensor according to various example embodiments of the inventive concepts; and

FIG. 15 is a cross-sectional view of an image sensor according to various example embodiments of the inventive concepts.

### DETAILED DESCRIPTION

Hereinafter, various example embodiments according to the inventive concepts will be described in detail with reference to the drawings in order to describe the inventive concepts in more detail. Herein, the terms indicating order, such as first, second, etc., are used to distinguish elements having the same/similar functions, and the ordinal numbers may be interchanged according to the order in which the terms are mentioned. The term “impurity” may also be referred to as “dopant”.

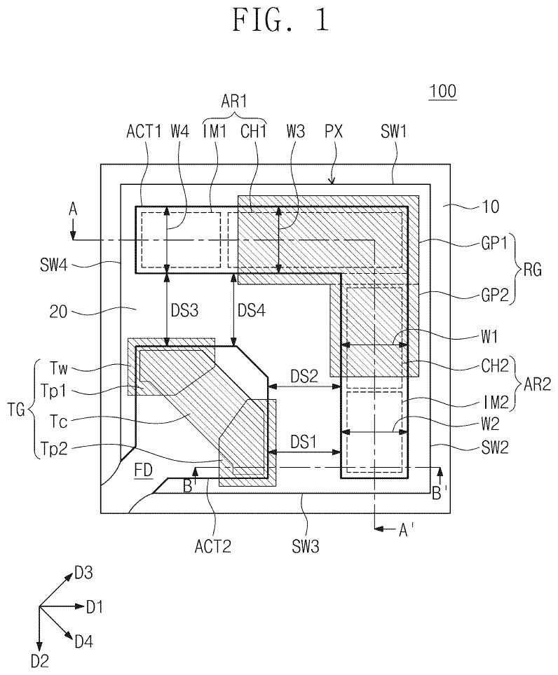

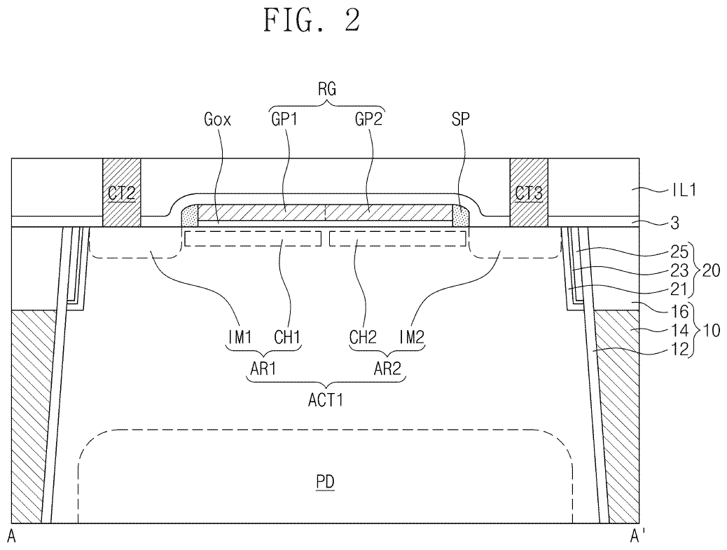

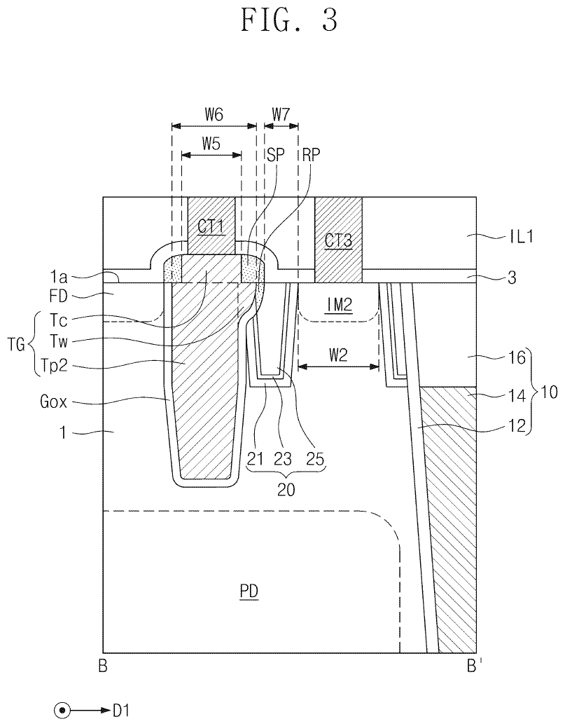

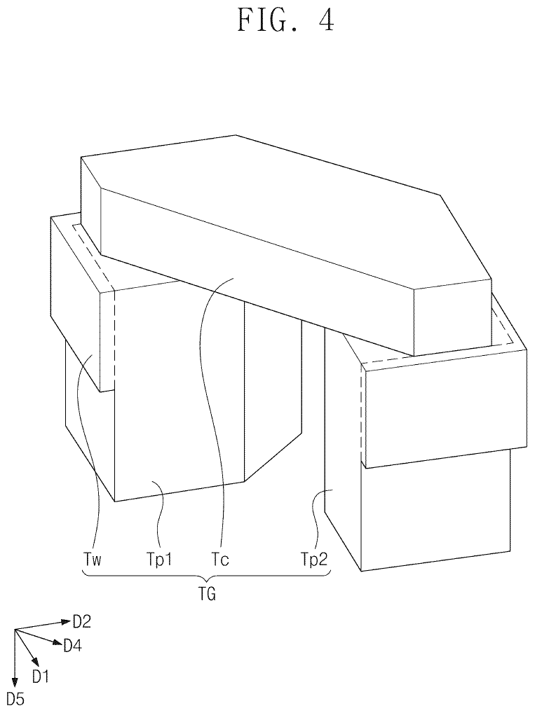

FIG. 1 is a schematic layout of an image sensor according to various example embodiments of the inventive concepts. FIG. 2 is a cross-sectional view taken along line A-A′ of FIG. 1. FIG. 3 is a cross-sectional view taken along line B-B′ of FIG. 1. FIG. 4 is a perspective view of the transfer gate electrode of FIGS. 1 and 3.

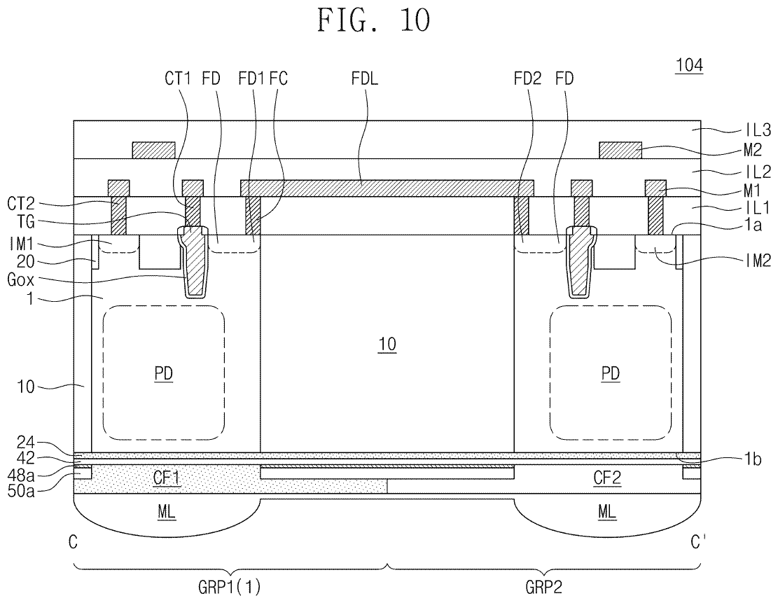

Referring to FIGS. 1 to 4, an image sensor 100 according to various example embodiments of the inventive concepts are provided with a substrate 1. The substrate 1 may include a plurality of light-receiving regions PX arranged two-dimensionally along a first direction D1 and a second direction D2 crossing each other. FIG. 1 illustrates one light-receiving region PX as an example. The substrate 1 may include a first face 1a and a second face 1b (FIG. 10) opposite to each other. Light may be incident into the substrate 1 through the second face 1b. The substrate 1 may be a silicon on insulator (SOI) substrate, an epitaxial layer, or a single-crystal wafer including silicon and/or germanium. However, example embodiments are not limited thereto. The substrate 1 may be doped with a first-conductive type impurity. The first conductive type may be, for example, a P type. The first-conductive type impurity may be, for example, boron. However, example embodiments are not limited thereto.

A deep separation part 10 isolating the light-receiving regions PX from each other and defining the same may be disposed in the substrate 1. The deep separation part 10 may have a mesh shape in a plan view. The deep separation part 10 may include an isolation conductive pattern 14 disposed therein, an isolation insulating pattern 12 between the isolation conductive pattern 14 and the substrate 1, and a first buried insulating pattern 16 on the isolation conductive pattern 14. The deep separation part 10 may penetrate the substrate 1. The isolation conductive pattern 14 may be formed of impurity-doped polysilicon or metal. The isolation insulating pattern 12 and the first buried insulating pattern 16 may be formed of an insulating material such as silicon oxide. However, example embodiments are not limited thereto.

A photoelectric conversion part PD may be disposed in the substrate 1 in the light-receiving region PX. The photoelectric conversion part PD may be doped with an impurity of a second conductive type opposite to the first conductive type. The second conductive type may be, for example, an N type. The second-conductive type impurity may be, for example, phosphorus or arsenic. However, example embodiments are not limited thereto. An N-type impurity region of the photoelectric conversion part PD may form a PN junction with a peripheral P-type impurity region of the substrate 1 so as to constitute a photodiode, and an electron-hole pair may be generated through the PN junction when light is incident.

A shallow separation part 20 may be disposed adjacent to the first face la in the substrate 1 in the light-receiving region PX and define first and second active parts ACT1 and ACT2. The shallow separation part 20 may be formed using a shallow trench isolation (STI) method. The shallow separation part 20 may include a first insulating liner 21, a second insulating liner 23, and a second buried insulating pattern 25 that are sequentially stacked. The second insulating liner 23 may include a material different from materials of the first insulating liner 21 and the second buried insulating pattern 25. For example, the second insulating liner 23 may be formed of silicon nitride, and the first insulating liner 21 and the second buried insulating pattern 25 may be formed of silicon oxide. The deep separation part 10 may penetrate the shallow separation part 20. No interface may be observed between the deep separation part 10 and the shallow separation part 20.

In a plan view, the light-receiving region PX may have first to fourth sidewalls SW1 to SW4 clockwise and sequentially arranged. The third and fourth sidewalls SW3 and SW4 may be disconnected without being connected to each other.

The first active part ACT1 may have an “L” shape or rotated “L” shape in a plan view. In detail, the first active part ACT1 includes a first active region AR1 elongated in the first direction D1 and adjacent to the first sidewall SW1 and a second active region AR2 elongated in the second direction D2 and adjacent to the second sidewall SW2. The first active region AR1 is connected to the second active region AR2.

Referring to FIGS. 1 and 2, a reset gate electrode RG is disposed on the first active part ACT1. The reset gate electrode RG may be formed of, for example, impurity-doped polysilicon. However, example embodiments are not limited thereto. A lower surface of the reset gate electrode RG is positioned on the first face la. Sidewalls of the reset gate electrode RG may be covered with a gate spacer SP. The gate spacer SP may be formed of, for example, silicon nitride. However, example embodiments are not limited thereto. A gate insulating layer Gox may be interposed between the reset gate electrode RG and the substrate 1. The gate insulating layer Gox may include a single-layered or multi-layered layer of at least one of silicon oxide, metal oxide, silicon nitride, or silicon oxynitride. However, example embodiments are not limited thereto.

The reset gate electrode RG may have an “L” shape or rotated “L” shape in a plan view. The reset gate electrode RG includes a first gate portion GP1 on the first active region AR1 and a second gate portion GP2 on the second active region AR2. The first gate portion GP1 is connected to the second gate portion GP2. A planar shape of the reset gate electrode RG having a bent structure may increase a channel length, thereby limiting or preventing a short channel effect. Such a planar shape of the reset gate electrode RG may be very effective to improve performance of an image sensor as a size of the light-receiving region PX decreases.

The first active region AR1 may include a first channel region CH1 overlapping the first gate portion GP1 and a first impurity region IM1 not overlapping the first gate portion GP1. The first channel region CH1 may overlap the gate spacer SP extending laterally from the first gate portion GP1 and covering a sidewall of the first gate portion GP1.

The second active region AR2 may include a second channel region CH2 overlapping the second gate portion GP2 and a second impurity region IM2 not overlapping the second gate portion GP2. The second channel region CH2 may overlap the gate spacer SP extending laterally from the second gate portion GP2 and covering a sidewall of the second gate portion GP2. The second channel region CH2 meets the first channel region CH1.

The second channel region CH2 may have a first width W1 in the first direction D1. The second impurity region IM2 may have a second width W2 in the first direction D1. In various example embodiments, the first width W1 is equal to the second width W2.

The first channel region CH1 may have a third width W3 in the second direction D2. The first impurity region IM1 may have a fourth width W4 in the second direction D2. In various example embodiments, the third width W3 is equal to the fourth width W4.

The first impurity region IM1 and the second impurity region IM2 may be doped with an impurity of a second conductive type opposite to the first conductive type of the impurity with which the substrate 1 is doped. The second conductive type may be, for example, an N type.

One of the first and second impurity regions IM1 and IM2 may be connected to a floating diffusion region FD or a capacitor for storing electrons of the floating diffusion region FD. A power supply voltage Vpix may be applied to the other one of the first and second impurity regions IM1 and IM2.

The second active part ACT2 may be adjacent to the third sidewall SW3 and the fourth sidewall SW4. The second active part ACT2 may be adjacent to the first active part ACT1 in a third direction D3 orthogonal to the first direction D1 and the second direction D2.

In various example embodiments, a first distance DS1 between the second active part ACT2 and the second impurity region IM2 may be equal to a second distance DS2 between the second active part ACT2 and the second channel region CH2. A third distance DS3 between the second active part ACT2 and the first impurity region IM1 may be equal to a fourth distance DS4 between the second active part ACT2 and the first channel region CH1.

Referring to FIGS. 1, 3, and 4, a transfer gate electrode TG is disposed on the second active part ACT2. The transfer gate electrode TG may be formed of impurity-doped polysilicon. However, example embodiments are not limited thereto. The transfer gate electrode TG includes a plurality of inserted parts Tp1 and Tp2 inserted into the substrate 1 and a connection part Tc connecting the plurality of inserted parts Tp1 and Tp2. The inserted parts Tp1 and Tp2 may include first and second inserted parts Tp1 and Tp2. The first and second inserted parts Tp1 and Tp2 may be spaced apart from each other in a fourth direction D4 intersecting the first to third directions D1 to D3. The connection part Tc may be disposed on the first face 1a of the substrate 1 and elongated in the fourth direction D4. The first and second inserted parts Tp1 and Tp2 and the connection part Tc may be integrated with each other. Upper portions of the first and second inserted parts Tp1 and Tp2 may be wider than lower portions thereof, respectively.

The upper portion of each of the first and second inserted parts Tp1 and Tp2 may have a sidewall protrusion Tw protruding toward and overlapping the shallow separation part 20. The connection part Tc may have a fifth width W5 in the first direction D1. The second inserted part Tp2 may have a sixth maximum width W6 in the first direction D1. The sixth maximum width W6 may be larger than the fifth width W5. A sidewall of the connection part Tc may be covered with the gate spacer SP. The gate spacer SP may be in contact with upper surfaces of the first and second inserted parts Tp1 and Tp2. In FIG. 3, an upper surface of the shallow separation part 20 may have a seventh width W7 in the first direction D1.

The gate insulating layer Gox may be interposed between the first and second inserted parts Tp1 and Tp2 and the substrate 1. The gate insulating layer Gox may be formed of, for example, silicon oxide. An insulating pattern RP may be interposed between the shallow separation part 20 and the sidewall protrusion Tw of each of the first and second inserted parts Tp1 and Tp2. The insulating pattern RP may be formed of the same material as that of the gate spacer SP. The insulating pattern RP may be connected to the gate spacer SP.

The floating diffusion region FD may be disposed in the second active part ACT2 on one side of the transfer gate electrode TG. The floating diffusion region FD may be doped with an impurity of a second conductive type opposite to the first conductive type of the impurity with which the substrate 1 is doped. The second conductive type may be, for example, an N type.

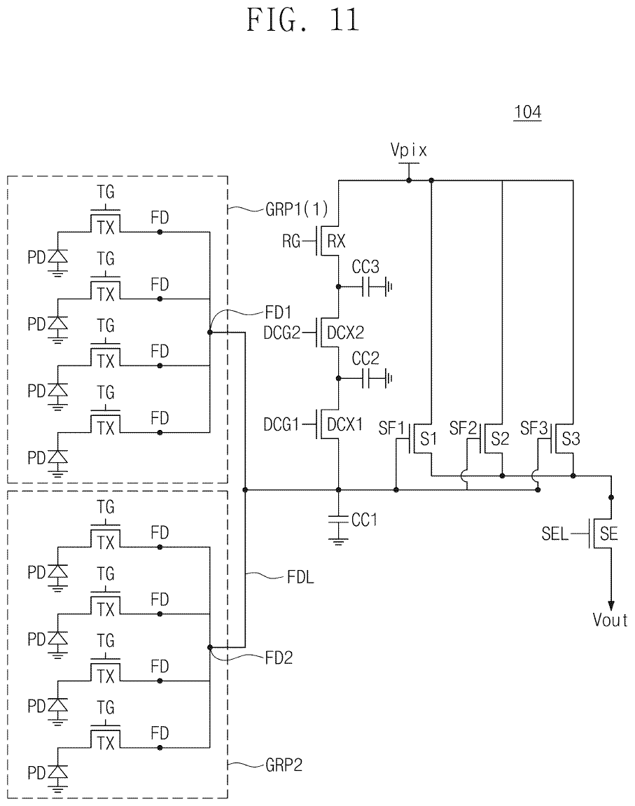

The first face 1a of the substrate 1, the transfer gate electrode TG, and the reset gate electrode RG may be covered with an etch stop layer 3. A first interlayer insulating layer IL1 is disposed on the etch stop layer 3. The etch stop layer 3 may be formed of silicon nitride. The first interlayer insulating layer IL1 may be formed of, for example, silicon oxide. However, example embodiments are not limited thereto. A first contact plug CT1 may penetrate the first interlayer insulating layer IL1 and the etch stop layer 3 and may be in contact with the transfer gate electrode TG. A second contact plug CT2 may penetrate the first interlayer insulating layer IL1 and the etch stop layer 3 and may be in contact with the first impurity region IM1. A third contact plug CT3 may penetrate the first interlayer insulating layer IL1 and the etch stop layer 3 and may be in contact with the second impurity region IM2. A capacitor CC3 (FIG. 11) may be connected to the second contact plug CT2 or the third contact plug CT3.

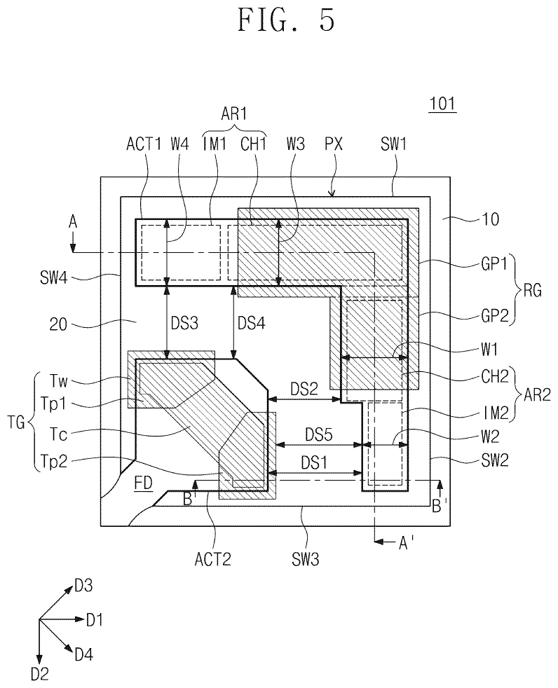

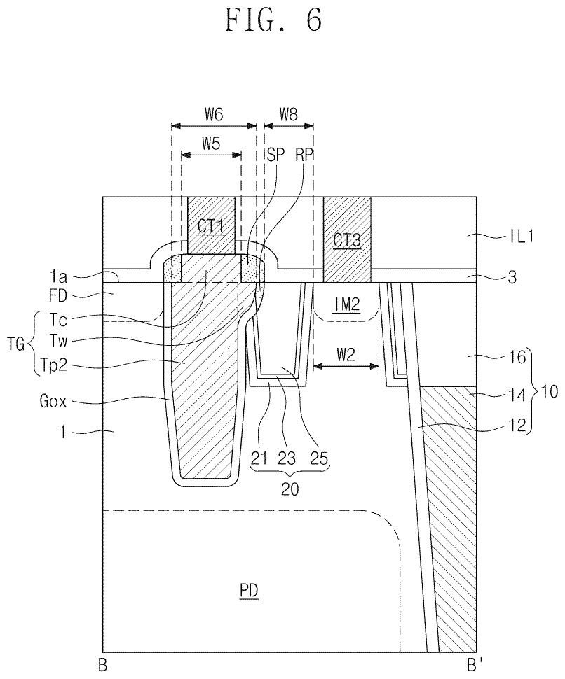

FIG. 5 is a layout of an image sensor according to various example embodiments of the inventive concepts. FIG. 6 is a cross-sectional view taken along line B-B′ of FIG. 5. A cross-section taken along line A-A′ of FIG. 5 may be the same as that illustrated in FIG. 2.

Referring to FIGS. 5 and 6, an image sensor 101 according to various example embodiments may be different from that of FIG. 1 with respect to a shape of the first active part ACT1. In various example embodiments, the power supply voltage Vpix may be applied to the first impurity region IM1. A capacitor for storing electrons of the floating diffusion region FD may be connected to the second impurity region IM2. The second impurity region IM2 may have the second width W2. The second channel region CH2 may have the first width W1. The second width W2 may be less than the first width W1.

The first distance DS1 between the second impurity region IM2 and the second active part ACT2 may be larger than the second distance DS2 between the second channel region CH2 and the second active part ACT2. The second impurity region IM2 is spaced a fifth distance DS5 apart from the transfer gate electrode TG. The fifth distance DS5 may be larger than the second distance DS2. In FIG. 6, the upper surface of the shallow separation part 20 may have an eighth width W8 in the first direction D1. The eighth width W8 may be larger than the seventh width W7 of FIG. 3.

Due to the shape of the first active part ACT1, the second impurity region IM2 may be farther away from the second active part ACT2 or the transfer gate electrode TG. Therefore, interference between the transfer gate electrode TG and the second impurity region IM2 may be reduced or suppressed, thereby reducing, or preventing leakage current in the second impurity region IM2. Accordingly, an image sensor is capable of providing a clear image and thereby making it possible to reduce or prevent defects such as white spots. Other structures may be the same as/similar to those described with reference to FIGS. 1 to 4.

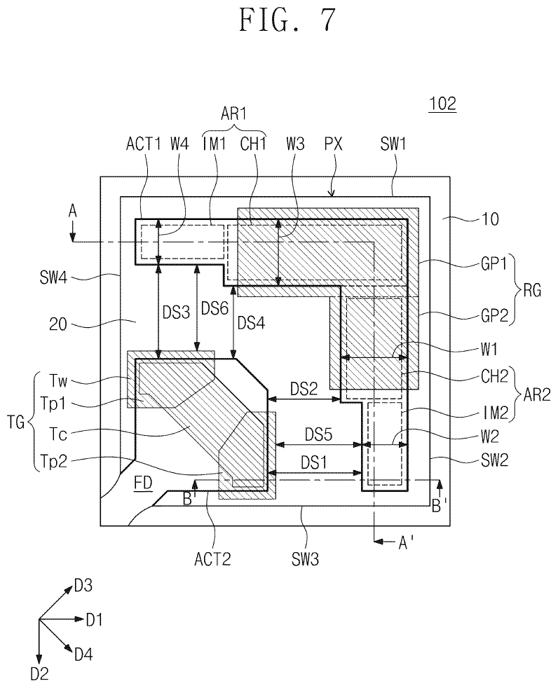

FIG. 7 is a layout of an image sensor according to various example embodiments of the inventive concepts. A cross-section taken along line A-A′ of FIG. 7 may be the same as that illustrated in FIG. 2. A cross-section taken along line B-B′ of FIG. 7 may be the same as that illustrated in FIG. 6.

Referring to FIG. 7, in an image sensor 102 according to various example embodiments, the fourth width W4 of the first impurity region IM1 may be less than the third width W3 of the first channel region CH1. The third distance DS3 between the first impurity region IM1 and the second active part ACT2 may be larger than the fourth distance DS4 between the first channel region CH1 and the second active part ACT2. A sixth distance DS6 between the transfer gate electrode TG and the first impurity region IM1 may be larger than the fourth distance DS4. Other structures may be the same as those described with reference to FIGS. 5 and 6.

Due to the shape of the first active part ACT1, the first impurity region IM1 may be farther away from the second active part ACT2 or the transfer gate electrode TG compared to the case of FIG. 5. Therefore, interference between the transfer gate electrode TG and the first impurity region IM1 may be reduced or suppressed. Accordingly, an image sensor capable of providing a clear image may be achieved.

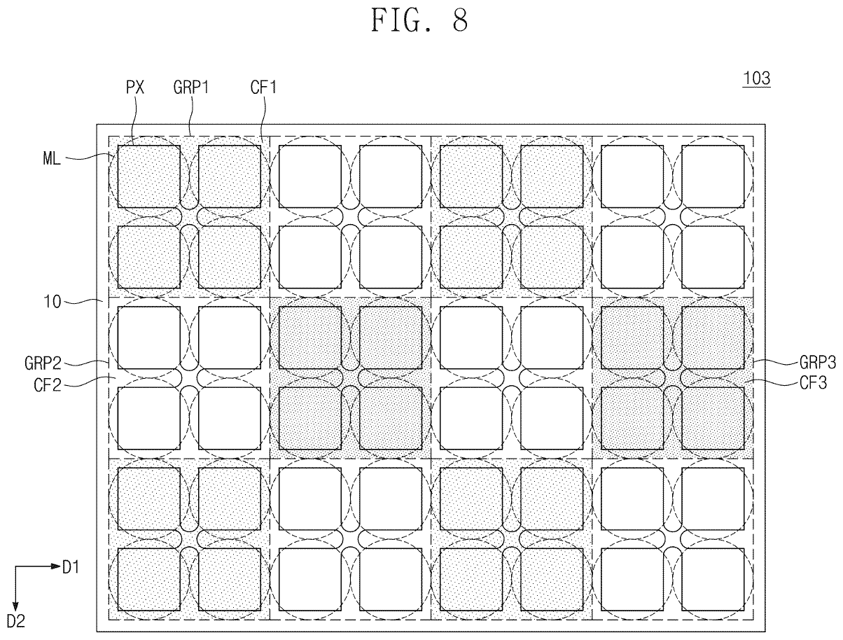

FIG. 8 is a plan view of an image sensor according to various example embodiments of the inventive concepts.

Referring to FIG. 8, an image sensor 103 according to various example embodiments may include first to third group regions GRP1, GRP2, and GRP3 arranged two-dimensionally along the first direction D1 and the second direction D2. The first and second group regions GRP1 and GRP2 may be repeatedly and alternately arranged in odd-numbered rows. The second and third group regions GRP2 and GRP3 may be repeatedly and alternately arranged in even-numbered rows. Each of the first to third group regions GRP1, GRP2, and GRP3 may include a 2×2 array of light-receiving regions PX. The deep separation part 10 may isolate the first to third group regions GRP1, GRP2, and GRP3 from each other. In a plan view, the deep separation part 10 may isolate the light-receiving regions PX from each other by being inserted into each of the group regions GRP1, GRP2, and GRP3. However, since the deep separation part 10 is cut at the center of each of the group regions GRP1, GRP2, and GRP3, the light-receiving regions PX belonging to one group region may be connected to each other. The first group region GRP1 may be covered with a first color filter CF1. The second group region GRP2 may be covered with a second color filter CF2. The third group region GRP3 may be covered with a third color filter CF3. The first color filter CF1 may have one color among, for example, red, green, and blue. The second color filter CF2 may have another color among red, green, and blue. The third color filter CF3 may have the remaining one color among red, green, and blue. Microlenses ML may be arranged on the first to third color filters CF1, CF2, and CF3. The microlenses ML may correspond to, and overlap, the light-receiving regions PX, respectively. That is, one microlens ML is disposed on one light-receiving region PX. A 2×2 array of microlenses ML may be arranged on one group region GRP1, GRP2, or GRP3. Such an array of the microlenses ML may increase a light collection rate of each light-receiving region PX so that a clear image may be achieved.

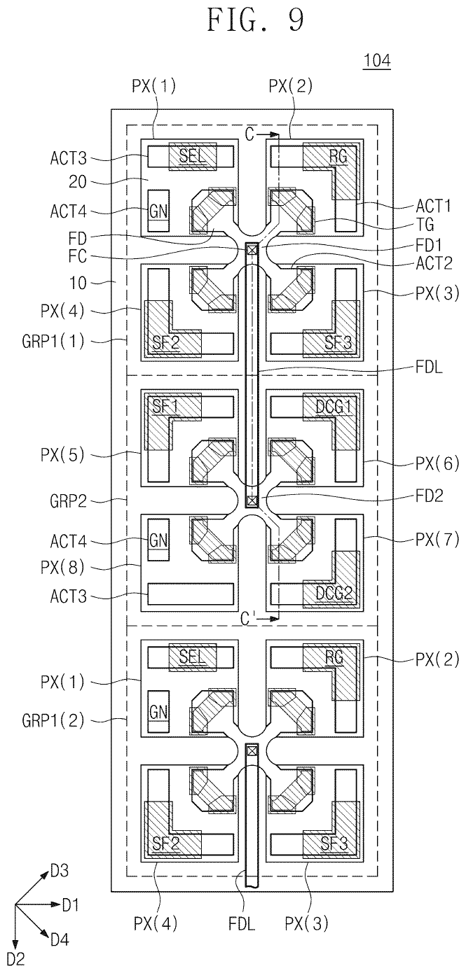

FIG. 9 is a layout of an image sensor according to various example embodiments of the inventive concepts. FIG. 10 is a cross-sectional view taken along line C-C′ of FIG. 9 according to various example embodiments of the inventive concepts. FIG. 11 is a circuit diagram of the image sensor of FIGS. 9 and 10. The plan view of FIG. 9 may correspond to a portion of FIG. 8.

Referring to FIGS. 9 to 11, an image sensor 104 according to the various example embodiments includes three group regions GRP1(1), GRP2, and GRP1(2) arranged along the second direction D2. The second group region GRP2 may be disposed between the first group regions GRP1(1) and GRP1(2). The group regions GRP1(1), GRP2, and GRP1(2) each include a 2×2 array of light-receiving regions PX arranged clockwise. The first group regions GRP1(1) and GRP1(2) each include first to fourth light-receiving regions PX(1) to PX(4) arranged clockwise. The second group region GRP2 includes fifth to eighth light-receiving regions PX(5) to PX(8) arranged clockwise.

The photoelectric conversion part PD may be disposed in the substrate 1 in each of the first to eighth light-receiving regions PX(1) to PX(8). The shallow separation part 20 is disposed adjacent to the first face la of the substrate 1 in each of the first to eighth light-receiving regions PX(1) to PX(8) so as to define active parts ACT1 to ACT4. The second to seventh light-receiving regions PX(2) to PX(7) each include the first active part ACT1. The first active part ACT1 may have an “L” shape or rotated “L” shape in a plan view.

The first to eighth light-receiving regions PX(1) to PX(8) each include the second active part ACT2. The second active parts ACT2 may be arranged adjacent to the center of each of the group regions GRP1(1), GRP2, and GRP1(2). The second active parts ACT2 may be connected to each other at the center of each of the group regions GRP1(1), GRP2, and GRP1(2).

The first and eighth light-receiving regions PX(1) and PX(8) include the third and fourth active parts ACT3 and ACT4. The third active part ACT3 may have a bar shape elongated in the first direction D1. The fourth active part ACT4 may have a bar shape elongated in the second direction D2. The first, third, and fourth active parts ACT1, ACT3, and ACT4 may be arranged adjacent to an edge of each of the group regions GRP1(1), GRP2, and GRP1(2).

The transfer gate electrodes TG and the floating diffusion region FD may be arranged on the second active parts ACT2 of the first to eighth light-receiving regions PX(1) to PX(8). The transfer gate electrode TG and the floating diffusion region FD disposed on one side thereof may constitute a transfer transistor TX. A first common floating diffusion region FD1 is disposed at the center of each of the first group regions GRP1(1) and GRP1(2). The first common floating diffusion region FD1 is connected to the floating diffusion regions FD of the first to fourth light-receiving regions PX(1) to PX(4). A second common floating diffusion region FD2 is disposed at the center of the second group region GRP2. The second common floating diffusion region FD2 is connected to the floating diffusion regions FD of the fifth to eighth light-receiving regions PX(5) to PX(8). FD contact plugs FC may be respectively disposed on the first and second common floating diffusion regions FD1 and FD2. An FD connection line FDL may be disposed on the first interlayer insulating layer IL1 covering the first face la of the substrate 1 so as to connect two adjacent FD contact plugs FC. Therefore, the first and second common floating diffusion regions FD1 and FD2 of two group regions adjacent to each other in the second direction D2 may be connected to each other. That is, the first and second common floating diffusion regions FD1 and FD2 of the first group region GRP1(1) located rearward among the first group regions GRP1(1) and GRP1(2) and the second group region GRP2 may be connected to each other through one FD connection line FDL. The first common floating diffusion region FD1 of the first group region GRP1(2) located frontward among the first group regions GRP1(1) and GRP1(2) is connected to the second common floating diffusion region FD2 of the other second group region GRP2 through another FD connection line FDL.

A selection gate electrode SEL may be disposed on the third active part ACT3 of the first light-receiving region PX(1). The fourth active part ACT4 of the eighth light-receiving region PX(8) may be doped with a second-conductive type impurity and used as a capacitor. Although not illustrated, a dummy gate electrode may be disposed on the fourth active part ACT4 of the eighth light-receiving region PX(8).

A ground region GN may be disposed in the fourth active part ACT4 of the eighth light-receiving region PX(8) and the first light-receiving region PX(1). The ground region GN may be disposed in the substrate 1 and doped with a first-conductive type impurity like the substrate 1. However, a concentration of the first-conductive type impurity of the ground region GN may be higher than that of the substrate 1.

The reset gate electrode RG may be disposed on the first active part ACT1 of the second light-receiving region PX(2). Planar shapes of the first active part ACT1 and the reset gate electrode RG may be the same as those described with reference to FIGS. 1 and 2.

A third source follower gate electrode SF3 is disposed on the first active part ACT1 of the third light-receiving region PX(3). A second source follower gate electrode SF2 is disposed on the first active part ACT1 of the fourth light-receiving region PX(4). A first source follower gate electrode SF1 is disposed on the first active part ACT1 of the fifth light-receiving region PX(5). A first dual conversion gain gate electrode DCG1 is disposed on the first active part ACT1 of the sixth light-receiving region PX(6). A second dual conversion gain gate electrode DCG2 is disposed on the first active part ACT1 of the seventh light-receiving region PX(7). The first to third source follower gate electrodes SF1 to SF3 and the first and second dual conversion gain gate electrodes DCG1 and DCG2 may each have an “L” shape or rotated “L” shape in a plan view. Accordingly, a short channel effect may be reduced or prevented and a clear image may be achieved in a highly integrated image sensor.

Referring to FIGS. 9 and 11, a second source follower transistor S2 including the second source follower gate electrode SF2 in the first group region GRP1(1) located rearward, a third source follower transistor S3 including the third source follower gate electrode SF3 in the first group region GRP1(1), and a first source follower transistor S1 including the first source follower gate electrode SF1 in the second group region GRP2 may be connected in parallel to each other. The first to third source follower gate electrodes SF1, SF2, and SF3 may be connected to the FD connection line FDL that connects the first and second common floating diffusion regions FD1 and FD2 of the second group region GRP2 and the first group region GRP1(1) located rearward. The FD connection line FDL may extend above and overlap the first to third source follower gate electrodes SF1, SF2, and SF3.

One terminal of each of the first to third source follower transistors S1 to S3 may be connected to one terminal of a selection transistor SE including the selection gate electrode SEL on the first group region GRP1(2) located frontward. Since the first to third source follower transistors S1 to S3 are connected in parallel, thermal noise and flicker noise may be reduced, and thus clear image quality may be achieved.

A first dual conversion gain transistor DCX1 including the first dual conversion gain gate electrode DCG1 on the second group region GRP2, a second dual conversion gain transistor DCX2 including the second dual conversion gain gate electrode DCG2 on the second group region GRP2, and a reset transistor RX including the reset gate electrode RG on the first group region GRP1(2) located frontward may be sequentially connected in series to each other. The FD connection line FDL may be connected to an impurity region (or drain region) on one side of the first dual conversion gain gate electrode DCG1. The FD connection line FDL may extend to and overlap the impurity region on one side of the first dual conversion gain gate electrode DCG1.

A first capacitor CC1 may be connected to the impurity region on the one side of the first dual conversion gain gate electrode DCG1. A second capacitor CC2 may be connected to an impurity region on one side of the second dual conversion gain gate electrode DCG2. A third capacitor CC3 may be connected to an impurity region IM1 or IM2 on one side of the reset gate electrode RG. The first to third capacitors CC1 to CC3 may be, for example, metal-insulator-metal (MIM) type capacitors.

In the image sensor 104 according to various example embodiments, electrons (charges) corresponding to incident light may be generated and accumulated in the photoelectric conversion part PD. When at least one of transfer transistors TX of the first group region GRP1(1) located rearward is turned on, a voltage level of the first common floating diffusion region FD1 connected thereto may be determined. The reset transistor RX may reset the first common floating diffusion region FD1. For example, in a state in which the first and second dual conversion gain transistors DCX1 and DCX2 are turned on, the reset transistor RX may electrically connect the first common floating diffusion region FD1 to the power supply voltage Vpix on the basis of an electric signal (reset signal) applied to the reset gate electrode RG. The reset transistor RX may remove or discharge electrons stored in the first common floating diffusion region FD1 by setting the voltage level of the first common floating diffusion region FD1 to the power supply voltage Vpix on the basis of the reset signal.

The first to third source follower gate electrodes SF1 to SF3 of the first to third source follower transistors S1 to S3 may be connected to the first common floating diffusion region FD1. The first to third source follower transistors S1 to S3 may output an output signal Vout to the selection transistor SE on the basis of the voltage level of the first common floating diffusion region FD1. A conversion gain may vary in response to on/off of the first and second dual conversion gain transistors DCX1 and DCX2.

Optical signals of the light-receiving regions PX in the second group region GRP2 may be detected by repeating the above process after detecting optical signals of the light-receiving regions PX in the first group region GRP1(1) located rearward.

Referring back to FIG. 10, first lines M1 may be arranged on the first interlayer insulating layer IL1. Second and third interlayer insulating layers IL2 and IL3 may be sequentially arranged on the first interlayer insulating layer IL1. Second lines M2 may be arranged between the second and third interlayer insulating layers IL2 and IL3.

A fixed charge layer 24 may be disposed on and in contact with the second face 1b. The fixed charge layer 24 may be in contact with the second face 1b. The fixed charge layer 24 may include a metal oxide layer or metal fluoride layer including an insufficient amount of oxygen or fluorine compared to a stoichiometric ratio. Accordingly, the fixed charge layer 24 may have a negative fixed charge. The fixed charge layer 24 may be formed of a metal oxide or metal fluoride including at least one metal selected from the group consisting of hafnium (Hf), zirconium (Zr), aluminum (Al), tantalum (Ta), titanium (Ti), yttrium, lanthanoid, and a combination thereof. However, example embodiments are not limited thereto. Hole accumulation may occur near the fixed charge layer 24. Therefore, occurrence of dark current and whites spot may be effectively reduced. The fixed charge layer 24 may be at least one of an aluminum oxide layer or a hafnium oxide layer.

An anti-reflective layer 42 may be disposed on the fixed charge layer 24. The anti-reflective layer 42 may include, for example, a silicon nitride. However, example embodiments are not limited thereto. A first grid pattern 48a and a second grid pattern 50a may be sequentially stacked on the anti-reflective layer 42. The first grid pattern 48a and the second grid pattern 50a may have a mesh shape in a plan view. The first grid pattern 48a and the second grid pattern 50a may expose the anti-reflective layer 42. The color filters CF1 and CF2 may be arranged under the anti-reflective layer 42. The microlenses ML may be arranged on the color filters CF1 and CF2.

The first grid pattern 48a may include a material that does not transmit light, for example, titanium. However, example embodiments are not limited thereto. A sidewall of the second grid pattern 50a may be aligned with a sidewall of the first grid pattern 48a. The first grid pattern 48a and the second grid pattern 50a may reduce or prevent crosstalk between adjacent light-receiving regions. The second grid pattern 50a may include an organic material. The second grid pattern 50a may have a lower refractive index than the color filters CF1 and CF2. For example, the second grid pattern 50a may have a refractive index of about 1.3 or less. Other structures may be the same as/similar to those described above.

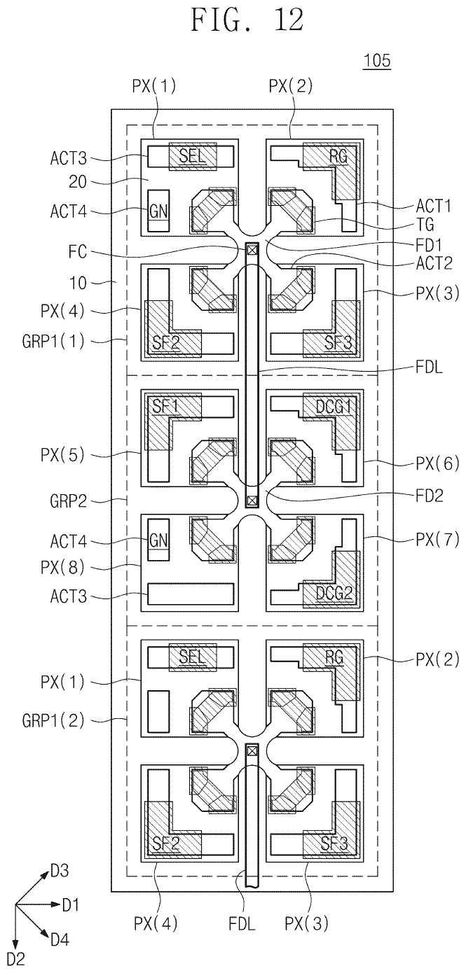

FIG. 12 is a layout of an image sensor according to various example embodiments of the inventive concepts.

Referring to FIG. 12, in an image sensor 105 according to the various example embodiments, the first active part ACT1 on which the reset gate electrode RG is disposed in the second light-receiving region PX(2) may have the same shape as the first active part ACT1 of FIG. 7. The first active part ACT1 on which the first dual conversion gain gate electrode DCG1 is disposed in the sixth light-receiving region PX(6) may have a rotated shape of the first active part ACT1 of FIG. 7. The first active part ACT1 on which the second dual conversion gain gate electrode DCG2 is disposed in the seventh light-receiving region PX(7) may have a rotated shape of the first active part ACTI of FIG. 7. In various example embodiments, since the first active parts ACT1 of the second light-receiving region PX(2), the sixth light-receiving region PX(6), and the seventh light-receiving region PX(7) have the same shape as the first active part ACT1 of FIG. 7, an interference phenomenon due to the transfer gate electrodes TG may be prevented/reduced, thus preventing/reducing leakage current of the capacitors CC1 to CC3. Accordingly, clear image quality may be achieved. At least one of the first active parts ACT1 of the second light-receiving region PX(2), the sixth light-receiving region PX(6), and the seventh light-receiving region PX(7) may have the shape of the first active part ACT1 of FIG. 5.

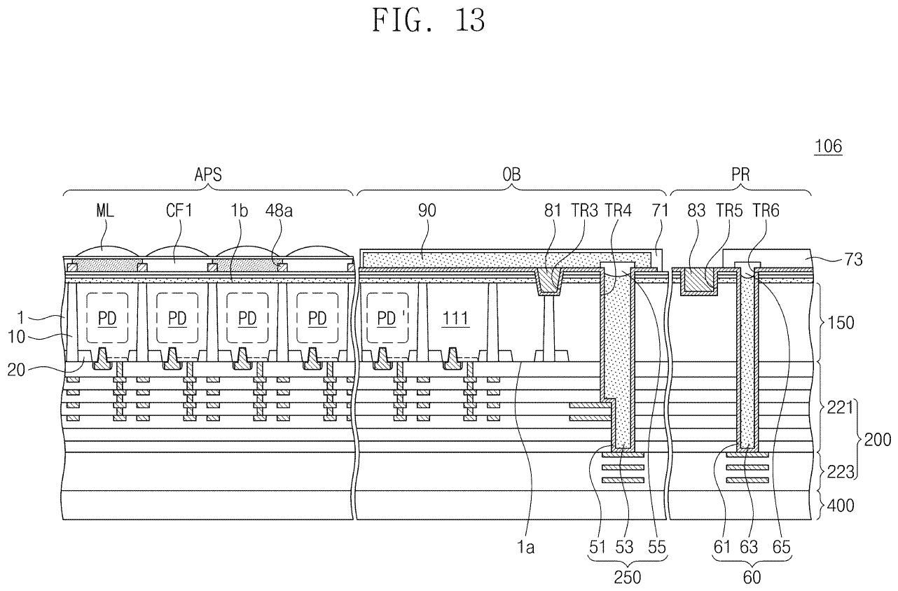

FIG. 13 is a cross-sectional view of an image sensor according to various example embodiments of the inventive concepts.

Referring to FIG. 13, an image sensor 106 according to various example embodiments of the inventive concepts may include the substrate 1 having a main region APS, an optical black region OB, and a pad region PR, a wiring layer 200 on the first face 1a of the substrate 1, and a base substrate 400 on the wiring layer 200.

The wiring layer 200 may have an upper wiring layer 221 and a lower wiring layer 223. The main region APS may include the light-receiving regions PX described with reference to FIGS. 1 to 12.

A first connection structure 250, a first conductive pad 81, and a bulk color filter 90 may be provided on the substrate 1 in the optical black region OB. The first connection structure 250 may include a first light shielding pattern 51, an insulating pattern 53, and a first capping pattern 55. The first light shielding pattern 51 may be formed of a conductive material. The first light shielding pattern 51 may include, for example, titanium or tungsten. However, example embodiments are not limited thereto.

The first light shielding pattern 51 may be provided on the second face 1b of the substrate 1. The first light shielding pattern 51 may conformally cover inner walls of a third trench TR3 and fourth trench TR4. The first light shielding pattern 51 may penetrate a photoelectric conversion layer 150 and the upper wiring layer 221 and connect the photoelectric conversion layer 150 to the wiring layer 200.

The first light shielding pattern 51 may be in contact with the isolation conductive pattern 14 of the deep separation part 10 of FIG. 3. The first conductive pad 81 may be electrically connected to the isolation conductive pattern 14 of the deep separation part 10. The first light shielding pattern 51 may block light incident to the optical black region OB.

The first conductive pad 81 may be provided in the third trench TR3 and may fill a remaining portion of the third trench TR3. The first conductive pad 81 may include a metal material, for example, aluminum. However, example embodiments are not limited thereto. A negative bias voltage may be applied to the isolation conductive pattern 14 through the first conductive pad 81. Accordingly, occurrence of dark current or white spots may be prevented/reduced.

The insulating pattern 53 may fill a remaining portion of the fourth trench TR4. The insulating pattern 53 may entirely or partially penetrate the photoelectric conversion layer 150 and the wiring layer 200. The first capping pattern 55 may be provided on an upper surface of the insulating pattern 53. The first capping pattern 55 may be provided on the insulating pattern 53.

The bulk color filter 90 may be provided on the first conductive pad 81, the first light shielding pattern 51, and the first capping pattern 55. The bulk color filter 90 may cover the first conductive pad 81, the first light shielding pattern 51, and the first capping pattern 55. A first protective layer 71 may be provided on the bulk color filter 90 and seal the bulk color filter 90.

The plurality of light-receiving regions PX may be also arranged in the optical black region OB, and a first reference photoelectric conversion part PD′ and a second reference region 111 may be arranged in these light-receiving regions PX. The first reference photoelectric conversion part PD′ provides a first reference charge amount that may be generated when light is blocked. The first reference charge amount may be used as a relative reference value when calculating an amount of charges generated from the light-receiving regions PX. The second reference region 111 provides a second reference charge amount that may be generated when the photoelectric conversion part PD is not present. The second reference charge amount may be used as information for removing process noise.

A second connection structure 60, a second conductive pad 83, and a second protective layer 73 may be provided on the substrate 1 in the pad region PR. The second connection structure 60 may include a second light shielding pattern 61, an insulating pattern 63, and a second capping pattern 65.

The second light shielding pattern 61 may be provided on the second face 1b of the substrate 1. The second light shielding pattern 61 may conformally cover inner walls of a fifth trench TR5 and sixth trench TR6. The second light shielding pattern 61 may penetrate the photoelectric conversion layer 150 and the upper wiring layer 221 and connect the photoelectric conversion layer 150 to the wiring layer 200. The second light shielding pattern 61 may be in contact with lines in the lower wiring layer 223. The second light shielding pattern 61 may be electrically connected to lines in the wiring layer 200. The second light shielding pattern 61 may include a metal material, for example, titanium or tungsten. However, example embodiments are not limited thereto.

The second conductive pad 83 may be provided in the fifth trench TR5 and may fill a remaining portion of the fifth trench TR5. The second conductive pad 83 may include a metal material, for example, aluminum. However, example embodiments are not limited thereto. The second conductive pad 83 may function as an electrical connection path to the outside of an image sensor device. The insulating pattern 63 may fill a remaining portion of the sixth trench TR6. The insulating pattern 63 may entirely or partially penetrate the photoelectric conversion layer 150 and the wiring layer 200. The second capping pattern 65 may be provided on the insulating pattern 63. A second protective layer 73 may cover a portion of the second light shielding pattern 61 and the second capping pattern 65.

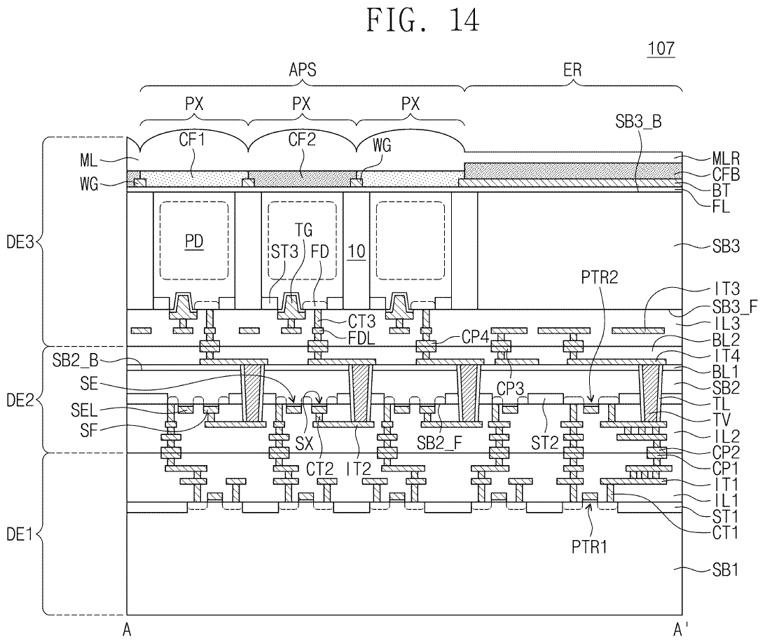

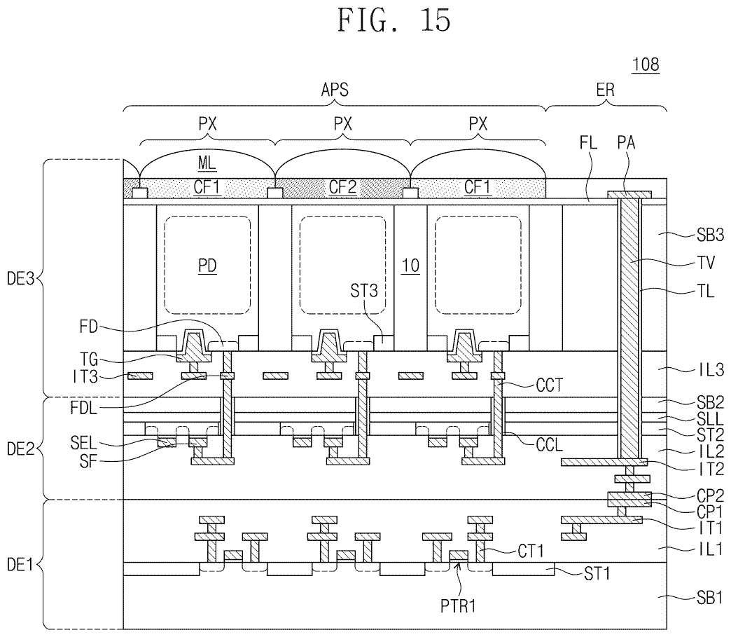

The image sensor structure described with reference to FIGS. 1 to 12 may be also applied to an image sensor with a 3-chip structure as illustrated in FIGS. 14 and 15.

FIG. 14 is a cross-sectional view of an image sensor according to various example embodiments of the inventive concepts.

Referring to FIG. 14, an image sensor 107 according to various example embodiments may have a structure in which first to third sub-chips DE1 to DE3 are sequentially stacked. In the specification, the ‘sub-chip’ can be called ‘semiconductor chip’. The first sub-chip DE1 includes a first substrate SB1 and a first interlayer insulating layer IL1 covering a front side of the first substrate SB1. The first substrate SB1 may be a semiconductor substrate or insulating substrate. The first interlayer insulating layer IL1 may have a single-layer or multi-layer structure of at least one of SiO₂, SiN, SiCN, SiON, or SiOCH. However, example embodiments are not limited thereto. Logic circuits may be arranged in the first sub-chip DE1. The logic circuits may include a row driver, a row decoder, a column decoder, a timing generator, a correlated double sampler (CDS), an analog-to-digital converter (ADC), etc. First peripheral transistors PTR1, first contact plugs CT1, and first lines IT1 may be arranged on the first substrate SB1 so as to constitute the logic circuits. A first shallow separation part ST1 may be disposed on the first substrate SB1 so as to define an active region for the first peripheral transistors PTR1. First conductive pads CP1 may be arranged at an upper end of the first interlayer insulating layer IL1.

The second sub-chip DE2 is bonded onto the first sub-chip DE1. The second sub-chip DE2 may include a second substrate SB2. A front side SB2_F of the second substrate SB2 may be covered with a second interlayer insulating layer IL2. The front side SB2_F of the second substrate SB2 may face the first sub-chip DE1. The driving transistors RX, DCX1, DCX2, SX1 to SX3, and SE illustrated in FIG. 11 may be arranged on the front side SB2_F of the second substrate SB2 in a main region of the second sub-chip DE2. Each of the gate electrodes RG, DCG1, DCG2, SF1, SF2, SF3, and SEL may have a shape of a planar type or vertical type. The driving transistors RX, DCX1, DCX2, SX1 to SX3, and SE may have a fin field-effect transistor (FinFET), multi bridge channel FET (MBCFET), or gate all around FET (GAAFET) structure.

Second peripheral transistors PTR2 may be arranged on the front side SB2_F of the second substrate SB2 in a peripheral region of the second sub-chip DE2. A second shallow separation part ST2 may be disposed on the front side SB2_F of the second substrate SB2 so as to define an active region for the driving transistors RX, DCX1, DCX2, SX, and SE and the second peripheral transistors PTR2. The second contact plugs CT2 and second lines IT2 may be arranged in the second interlayer insulating layer IL2. Second conductive pads CP2 may be arranged at a lower end of the second interlayer insulating layer IL2. A lower surface of the second interlayer insulating layer IL2 may be in contact with an upper surface of the first interlayer insulating layer IL1. The second conductive pads CP2 may be in contact with the first conductive pads CP1, respectively. There may be no boundary surface between the second conductive pads CP2 and the first conductive pads CP1 that are respectively in contact with the second conductive pads CP2, and the first and second conductive pads CP1 and CP2 corresponding to each other may be integrated.

A rear side SB2_B of the second substrate SB2 may be sequentially covered with first and second rear insulating layers BL1 and BL2. Fourth lines IT4 may be arranged in the second rear insulating layer BL2. Third conductive pads CP3 may be arranged at an upper end of the second rear insulating layer BL2. Through vias TV may penetrate the first rear insulating layer BL1, the second substrate SB2, the second shallow separation part ST2, and a portion of the second interlayer insulating layer IL2 and may be in contact with some of the second lines IT2, respectively. The through vias TV may be tapered downward. A via insulating layer TL may be interposed between the through vias TV and the second substrate SB2.

The third sub-chip DE3 is bonded onto the second sub-chip DE2. The third sub-chip DE3 includes a third substrate SB3. The third substrate SB3 may include a main region APS and an edge region ER. The main region APS may include the plurality of light-receiving regions PX. The deep separation part 10 may be disposed in the third substrate SB3 and may isolate the light-receiving regions PX from each other. The photoelectric conversion part PD is disposed in the third substrate SB3 in each of the light-receiving regions PX. A front side SB3_F of the third substrate SB3 may face the second sub-chip DE2. A third shallow separation part ST3 may be disposed on the front side SB3_F of the third substrate SB3 so as to define active regions for the transfer transistors TX (FIG. 11) and ground regions GN.

The transfer gate electrodes TG and floating diffusion regions FD may be arranged on the front side SB3_F of the third substrate SB3. The front side SB3_F of the third substrate SB3 may be covered with a third interlayer insulating layer IL3. Third contact plugs CT3, FD connection lines FDL, third lines IT3, etc., may be arranged in the third interlayer insulating layer IL3. The FD connection lines FDL may each connect at least a portion of the floating diffusion regions FD of a plurality of neighboring light-receiving regions PX. The floating diffusion regions FD of the third sub-chip DE3 may be connected to the source follower gate electrodes SF1 to SF3 of the source follower transistors SX1 to SX3 of the second sub-chip DE2.

A lower surface of the third interlayer insulating layer IL3 may be in contact with an upper surface of the second rear insulating layer BL2 of the second sub-chip DE2. Fourth conductive pads CP4 may be arranged at a lower end of the third interlayer insulating layer IL3. The fourth conductive pads CP4 may be in contact with the third conductive pads CP3, respectively. There may be no boundary surface between the fourth conductive pads CP4 and the third conductive pads CP3 that are respectively in contact with the fourth conductive pads CP4, and the third and fourth conductive pads CP3 and CP4 corresponding to each other may be integrated.

A rear side SB3_B of the third substrate SB3 may be covered with a third rear insulating layer FL. The third rear insulating layer FL may include at least one of a fixed charge layer, an anti-reflective layer, a planarization layer, or a protective layer. A grid pattern WG, color filters CF1, CF2, and CF3, and microlenses ML may be arranged on the third rear insulating layer FL in the main region APS. A first optical black pattern BT, a second optical black pattern CFB, and a lens residual layer MLR may be sequentially arranged on the third rear insulating layer FL in the edge region ER. The first optical black pattern BT may have the same material and the same thickness as the grid pattern WG. The second optical black pattern CFB may include a blue color filter. The lens residual layer MLR may have the same material as the microlenses ML. Other structures may be the same as/similar to those described above.

FIG. 15 is a cross-sectional view of an image sensor according to various example embodiments of the inventive concepts.

Referring to FIG. 15, an image sensor 108 according to various example embodiments may have a structure in which first to third sub-chips DE1 to DE3 are sequentially stacked. The first sub-chip DE1 may be the same as/similar to that described with reference to FIG. 10A. The second sub-chip DE2 and the third sub-chip DE3 may be similar to those described with reference to FIG. 14. The second substrate SB2 may be a semiconductor substrate, an insulating substrate, or a silicon on insulator (SOI) substrate. The first conductive pads CP1 may be arranged at an upper end of the first sub-chip DE1.

A substrate insulating layer SLL may be disposed in the second substrate SB2 of the second sub-chip DE2. A through contact plug CCT may penetrate the second substrate SB2, a portion of the second interlayer insulating layer IL2, and a portion of the third interlayer insulating layer IL3 and connect the FD connection line FDL to the source follower gate electrodes SF1 to SF3. A through contact insulating layer CCL may be interposed between the through contact plug CCT and the second substrate SB2. The second conductive pads CP2 may be arranged at a lower end of the second sub-chip DE2. The second conductive pads CP2 may be in contact with the first conductive pads CP1, respectively.

An input/output pad PA may be disposed on the third rear insulating layer FL in the edge region ER of the third sub-chip DE3. The through via TV may penetrate the third substrate SB3 and third interlayer insulating layer IL3 of the third sub-chip DE3, and the second substrate SB2 and a portion of the second interlayer insulating layer IL2 of the second sub-chip DE2 and connect the input/output pad PA to the second lines IT2. Other structures may be the same as/similar to those described with reference to FIG. 14.

In the specification, a concept of individual semiconductor chips (or sub-chips) may be defined by a stacked structure formed by several semiconductor wafers which are different from each other. An interface between the semiconductor chips may not be definitely observed because of bonding shape, bonding method, or bonding material between the semiconductor chips, and the stacked structure having an ambiguous interface is not excluded from the concept of the individual semiconductor chips.

An image sensor according to various example embodiments of the inventive concepts includes a reset gate electrode having a bending structure in a plan view so as to increase a channel length, thereby limiting or preventing a short channel effect. Furthermore, a planar shape of a first active part is modified so that an end of the first active part on which the reset gate electrode is disposed is located farther away from a second active part on which a transfer gate electrode is disposed, and thus an image sensor that provides clearer image quality and may prevent or reduce defects such as white spots by reducing current leakage may be provided.

Although various example embodiments of the inventive concepts have been described with reference to the accompanying drawings, those of ordinary skill in the art may easily understand that the example embodiments may be carried out in other specific forms without changing the technical concepts or essential features. Therefore, the above example embodiments should be considered illustrative and should not be construed as limiting. The example embodiments of FIGS. 1 to 15 may be combined with each other.

What is claimed is:

1. An image sensor comprising:
a substrate including a first face and a second face opposite to each other;
a deep separation part in the substrate and defining a first light-receiving region;
the first light-receiving region including first to fourth side surfaces arranged clockwise in a plan view;
a shallow separation part in the substrate and adjacent to the first face, the shallow separation part defining a first active part in the first light-receiving region, and the first active part having a first active region adjacent to the first side surface and a second active region adjacent to the second side surface in a plan view; and
a reset gate electrode on the first active part,
wherein the reset gate electrode includes a first gate portion on the first active region and a second gate portion on the second active region, and
the first gate portion and the second gate portion are connected to each other.

2. The image sensor of claim 1, wherein
the deep separation part further defines a second light-receiving region,
the image sensor further comprises a dual conversion gain gate electrode on the second light-receiving region, and
the dual conversion gain gate electrode has an “L” shape in a plan view.

3. The image sensor of claim 1, wherein
the shallow separation part further defines a second active part in the first light-receiving region,
the image sensor further comprises a transfer gate electrode on the second active part and a floating diffusion region in the second active part,
the second active part is located between the third side surface and the fourth side surface,
the second active region includes a first channel region overlapping the second gate portion and a first impurity region not overlapping the second gate portion, and
a first distance between the second active part and the first impurity region is larger than a second distance between the second active part and the first channel region.

4. The image sensor of claim 3, wherein
the first active region includes a second channel region overlapping the first gate portion and a second impurity region not overlapping the first gate portion, and
a third distance between the second active part and the second impurity region is larger than a fourth distance between the second active part and the second channel region.

5. The image sensor of claim 3, wherein a third distance between the transfer gate electrode and the first impurity region is larger than the second distance.

6. The image sensor of claim 3, wherein the transfer gate electrode includes:
a plurality of inserted parts in the substrate and spaced apart from each other; and
a connection part on the substrate and connecting the inserted parts to each other.

7. The image sensor of claim 6, wherein
an upper portion of one of the inserted parts has a first width in a first direction,
the connection part has a second width in the first direction, and
the first width is larger than the second width.

8. The image sensor of claim 6, further comprising:
a spacer covering a sidewall of the connection part; and
an insulating pattern between the shallow separation part and an upper portion of one of the inserted parts,
wherein the spacer and the insulating pattern include a same material.

9. The image sensor of claim 1,
wherein the deep separation part further defines second to fourth light-receiving regions adjacent to the first light-receiving region in the substrate,
the first to fourth light-receiving regions are arranged clockwise and constitute a first group region,
the shallow separation part is in each of the first to fourth light-receiving regions and defines second active parts,
the second active parts are connected to each other at a center of the first group region, and
the first active part is adjacent to an edge of the first group region.

10. The image sensor of claim 9, further comprising:
a first color filter on the second face and covering the first group region; and
microlenses arranged on the first color filter and respectively overlapping the first to fourth light-receiving regions.

11. An image sensor comprising:
a substrate including a first face and a second face opposite to each other;
a deep separation part in the substrate and defining a first light-receiving region;
a shallow separation part in the substrate and adjacent to the first face, the shallow separation part defining a first active part and a second active part in the first light-receiving region, and the first active part having an “L” shape in a plan view;
a reset gate electrode on the first active part;
a transfer gate electrode on the second active part; and
a floating diffusion region in the second active part adjacent to the transfer gate electrode,
wherein the first active part includes a channel region overlapping the reset gate electrode and a first impurity region not overlapping the reset gate electrode, and
a first distance between the second active part and the first impurity region is larger than a second distance between the second active part and the channel region.

12. The image sensor of claim 11, wherein
the transfer gate electrode includes:
a plurality of inserted parts in the substrate and spaced apart from each other; and
a connection part on the substrate and connecting the inserted parts to each other,
wherein an upper portion of one of the inserted parts has a first width in a first direction,
the connection part has a second width in the first direction, and
the first width is larger than the second width.

13. The image sensor of claim 12, further comprising:
a spacer covering a sidewall of the connection part; and
an insulating pattern between the shallow separation part and the upper portion of one of the inserted parts,
wherein the spacer and the insulating pattern include a same material.

14. The image sensor of claim 11, wherein the reset gate electrode has an “L” shape in a plan view.

15. The image sensor of claim 11,
wherein the deep separation part further defines a second light-receiving region,
the image sensor further comprises a dual conversion gain gate electrode on the second light-receiving region, and
the dual conversion gain gate electrode has an “L” shape in a plan view.

16. An image sensor comprising:
a substrate including a first face and a second face opposite to each other;
a deep separation part in the substrate and separating first and second group regions arranged side by side in a first direction such that the deep separation part is in the first and second group regions and separates first to eighth light-receiving regions, the first to fourth light-receiving regions are arranged clockwise and constitute the first group region, and the fifth to eighth light-receiving regions are arranged clockwise and constitute the second group region;
a shallow separation part in the substrate and adjacent to the first face in the first to eighth light-receiving regions, the shallow separation part defining a first active part and a second active part in each of the first to eighth light-receiving regions;
a reset gate electrode on the first active part in any one of the first to fourth light-receiving regions and having an “L” shape in a plan view;
transfer gate electrodes respectively arranged on the second active parts of the first to eighth light-receiving regions;
a first floating diffusion region at a center of the first group region;
a second floating diffusion region at a center of the second group region;
a first line connecting the first floating diffusion region to the second floating diffusion region;
an interlayer insulating layer covering the first face, the reset gate electrode, the transfer gate electrodes, and the first line;
a first color filter on the second face and covering the first group region;
a second color filter on the second face and covering the second group region; and
microlenses arranged on the first and second color filters and respectively overlapping the first to eighth light-receiving regions.

17. The image sensor of claim 16, wherein
the second active parts are arranged adjacent to centers of the first and second group regions,
the first active parts are arranged adjacent to edges of the first and second group regions, and
at least one or more of the first active parts has an “L” shape in a plan view.

18. The image sensor of claim 16, wherein
the first active part of any one of the first to fourth light-receiving regions includes a first channel region overlapping the reset gate electrode and a first impurity region not overlapping the reset gate electrode,
the first channel region has a first width in a second direction intersecting the first direction,
the first impurity region has a second width in the second direction, and
the second width is less than the first width.

19. The image sensor of claim 16, further comprising:
a dual conversion gain gate electrode on the first active part of any one of the fifth to eighth light-receiving regions; and
the dual conversion gain gate electrode having an “L” shape in a plan view.

20. The image sensor of claim 19, wherein
the first active part of any one of the fifth to eighth light-receiving regions includes a second channel region overlapping the dual conversion gain gate electrode and a second impurity region not overlapping the dual conversion gain gate electrode,
the second channel region has a third width in the second direction,
the second impurity region has a fourth width in the second direction, and
the fourth width is less than the third width.
